(19) United States
(12) Patent Application Publication
(10) Pub. No.: US 2026/0156965 A1
(43) Pub. Date: Jun. 4, 2026

(54) IMPROVEMENTS IN SILICON SOLAR PHOTOVOLTAIC CELL EFFICIENCY

(71) Applicant: The University of Tulsa, Tulsa, OK (US)

(72) Inventor: Parameswar Harikumar, Tulsa, OK (US)

(73) Assignee: The University of Tulsa, Tulsa, OK (US)

(21) Appl. No.: 19/110,087

(22) PCT Filed: Dec. 7, 2023
(86) PCT No.: PCT/US2023/082881

§ 371 Date: Mar. 9, 2025

Related U.S. Application Data
(60) Provisional application No. 63/431,340, filed on Dec. 9, 2022.

(51) Int. Cl. H10F 77/30; H10F 77/40

(52) U.S. Cl. CPC H10F 77/315; H10F 77/496

(57) ABSTRACT

An apparatus and a method for producing a photovoltaic solar cell. The apparatus includes a planar silicon base. At least one thin film layer of vanadium (V) doped zinc oxide (ZnO), at least one thin film layer of perovskite precursor solution, or at least one thin film layer of perovskite quantum dots is applied on said silicon base to enhance efficiency and prolong life of the solar cell. A layer of polydimethylsiloxane may be applied to prolong life of the perovskite quantum dots.

### PRIORITY

This application is based on and claims priority to U.S. Provisional Application No. 63/431,340 filed Dec. 9, 2022.

### FEDERALLY SPONSORED RESEARCH OR DEVELOPMENT

This invention was made with government support under FA86922P0818-TU1 and FA86922P0836-TU1 awarded by the U.S. Air Force. The U.S. Government may have rights in this invention.

### BACKGROUND OF THE INVENTION

### Field of the Invention

The present invention is directed to an apparatus and to a method for enhancing efficiency of silicon photovoltaic solar cells.

### Description of the Related Art

A solar or photovoltaic cell converts the energy of light directly into electricity by the photovoltaic effect, a physical and chemical phenomenon.

When a semiconductor is exposed to light, it absorbs the light's energy and transfers it to negatively charged electrons. This extra energy allows the electrons to flow through the material as an electrical current.

The power conversion efficiency of a photovoltaic (PV) cell is the amount of electrical power coming out of the cell compared to the energy from the light shining on it, which indicates how effective the cell is at converting energy from one form to the other. The power conversion efficiency is a parameter defined by the fraction of incident power converted into electricity.

An important property of PV semiconductors is the bandgap, which indicates what wavelengths of light the material can absorb and convert to electrical energy.

Crystalline silicon represents more than 90% of the total photovoltaic market.

While improvements in efficiency of solar cells have been made over the years, improvements over the past two decades have plateaued and have only been about one percent (1%). Currently, the best silicon solar cells in the residential market are capped at about 20 percent efficiency, with a lifetime of approximately 25 years. It will be appreciated that the impact of even a small improvement in efficiency would be enormous and would facilitate more widespread use of solar cells.

There is a fundamental problem in the structure of silicon solar cells that limit their efficiency. This problem is illustrated in the mismatch between solar spectrum on earth and absorption spectrum of crystalline silicon as shown in the chart in FIG. 1 showing wavelength on the x-axis and spectral irradiance on the y-axis.

There are at least three known approaches to facilitating photons to a silicon structure to optimize absorption. The three separate processes are illustrated diagrammatically in FIG. 2. In a first known process, long wavelength photons (two red photons for example) are absorbed (multiple photon process) and a short wavelength photon (a green photon) is emitted by a process called up conversion (UC). In a second known process, called down conversion (DC), short wavelength photons are absorbed and long wavelength photons are emitted;

A third process is employed in the present invention called downshifting, as shown in FIG. 2. Photons of short and mid-range wavelengths are absorbed and converted to wavelengths shifted to more closely match the absorption profile of the solar cell. The efficiency profile of the solar cell is thus controlled. Thus, there is compensation for the mismatch between the solar spectrum and absorption spectrum by downshifting.

The present invention facilitates downshifting of wavelengths so that silicon can absorb wavelengths in the range suitable for conversion. This is achieved by coating silicon with thin film layers nano meters in thickness. The nominal cost of adding thin film layers is a few pennies on the dollar.

Accordingly, it is a principal object and purpose of the present invention to increase efficiency of silicon photovoltaic cells.

It is a further object and purpose of the present invention to increase efficiency of silicon photovoltaic cells by coating the cells with one or more thin layers of vanadium (V) doped zinc oxide (ZnO) on top of the silicon base.

It is a further object and purpose of the present invention to increase efficiency of silicon photovoltaic cells by coating the cells with one or more thin layers of perovskite precursor solution on said silicon base.

It is a further object and purpose of the present invention to manufacture solar cell modules having a crystalline silicon base with a plurality of thin film layers thereon.

It is a further object and purpose of the present invention to increase efficiency of silicon photovoltaic cells by coating the cells with one or more thin layers of perovskite quantum dots doped with Chlorine, Bromine, or Iodine on said silicon base.

It is a further object and purpose of the present invention to protect perovskite quantum dots from environmental degradation by the application of a layer of polydimethylsiloxane over the thin layers of perovskite quantum dots.

It is a further object and purpose of the present invention to retrofit existing solar cell modules by applying thin film layers on solar cells in order to enhance the efficiency and to prolong the life of the solar cells.

### SUMMARY OF THE INVENTION

The present invention is directed to an apparatus and to a method to produce a solar cell having increased efficiency and longer life.

The apparatus includes a photovoltaic solar cell having a crystalline silicon base. In one preferred embodiment, at least one thin film layer of vanadium (V) doped zinc oxide (ZnO) is applied on top of the silicon base. A plurality of thin film layers may be utilized.

In another preferred embodiment, at least one thin film layer of a perovskite precursor solution is applied on the silicon solar base. A plurality of thin film layers may be utilized.

In another preferred embodiment, at least one thin film layer of perovskite quantum dots is applied on the silicon solar base. The perovskite quantum dots may be doped with Chlorine, Bromine, or Iodine. The thin film layer may comprise quantum dots doped in a ratio of 1:2 Bromine to Chlorine. A plurality of thin film layers may be utilized.

In another preferred embodiment, a layer of polydimethylsiloxane may be applied over the top of the thin film layer of perovskite quantum dots.

The present invention may be utilized in the manufacture of solar cell modules and may also be utilized by retrofitting existing silicon modules with the addition of a layer or layers of thin film.

### BRIEF DESCRIPTION OF THE DRAWINGS

FIG. 1 is a chart illustrating the mismatch between terrestrial solar spectrum and crystalline silicon absorption spectrum;

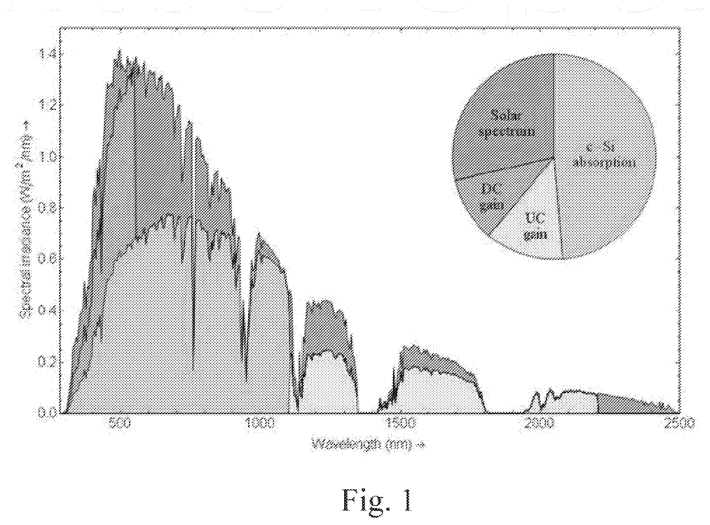

FIG. 2 is a chart diagrammatically illustrating three known processes to optimize crystalline silicon spectrum absorption;

FIG. 3 is a chart illustrating the increase in efficiency utilizing one preferred embodiment of the present invention having at least one thin layer of vanadium doped zinc oxide;

FIG. 4 is a chart of the samples in FIG. 3;

FIG. 5 is a chart illustrating the increases in efficiency utilizing another preferred embodiment of the present invention having at least one thin layer of a perovskite precursor solution;

FIG. 6 is a chart illustrating the photoluminescence of perovskite quantum dots of varying sizes and doping with Chlorine, Bromine, and Iodine;

FIG. 7 is two charts illustrating the efficiency increase of varying numbers of coated layers of perovskite quantum dots doped in a 1:1 Bromine to Chlorine ratio on two areas of solar cells;

FIG. 8 is two charts illustrating the efficiency increase of varying numbers of coated layers of perovskite quantum dots doped in a 1:2 Bromine to Chlorine ratio on two areas of solar cells;

FIG. 9 is a table illustrating the efficiency increase of perovskite quantum dots doped in a 1:1 Bromine to Chlorine ratio compared to perovskite quantum dots doped in a 1:2 Bromine to Chlorine ratio on two areas of solar cells;

FIG. 10 is a drawing of a moth-eye pattern of applied polydimethylsiloxane;

FIG. 11 is a drawing of an inverted pyramidal pattern of applied polydimethylsiloxane; and

FIG. 12 shows two charts showing the effect of encapsulation of perovskite quantum dots by polydimethylsiloxane on two areas of solar cells.

### DETAILED DESCRIPTION OF THE INVENTION

The embodiments discussed herein are merely illustrative of specific manners in which to make and use the invention and are not to be interpreted as limiting the scope.

While the invention has been described with a certain degree of particularity, it is to be noted that many modifications may be made in the details of the invention's construction and the arrangement of its components without departing from the scope of this disclosure. It is understood that the invention is not limited to the embodiments set forth herein for purposes of exemplification.

The present invention is directed to a solar cell apparatus and to a method to produce a solar cell module having improved efficiency and increased longevity. The present invention accomplishes the foregoing by enhancing sunlight absorption while suppressing reflection.

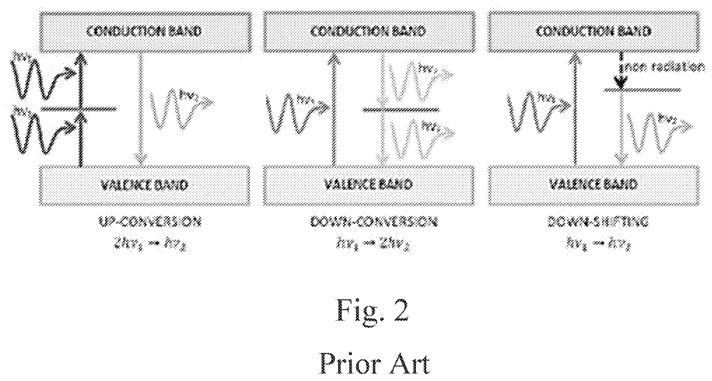

As shown in FIG. 2, downshifting is utilized. Photons of short and mid-range wavelengths are absorbed and converted to wavelengths shifted to match the absorption profile of the solar cell. By carefully attaching an absorbing thin film layer or layers on a silicon solar cell, the efficiency profile of the solar cell is controlled and improved, compensating for the mismatch between the solar spectrum and absorption by downshifting.

The present invention facilitates downshifting of wavelengths so that crystalline silicon can absorb wavelengths in the range suitable for conversion. This is achieved by coating silicon with thin film layers having a thickness of nano meters.

The thin film layer or layers may be installed in a number of ways. In one process, the thin film layer is installed by spin coating an initially liquid layer of the vanadium doped zinc oxide in a solvent on the silicon base, which dries to result in a thin film solid layer on the silicon.

In one preferred embodiment of the invention, a photovoltaic solar module is produced by providing a crystalline silicon base. At least one thin film layer of vanadium (V) doped zinc oxide (ZnO) is applied on the silicon base.

The J-V curve of a solar cell can be used to evaluate the power conversion efficiency (PCE). The measurement is to apply the voltage while measuring the current with a load resistor. Voc and Jsc represent the open-circuit voltage and short-circuit current density, respectively. The lower series resistance (Rs) and higher shunt resistance (Rsh) results in a higher fill factor (FF). The PCE can be obtained when the Voc, Jsc and FF are obtained from the J-V curve.

In one preferred embodiment of the invention, a photovoltaic solar module is produced by providing a crystalline silicon base. At least one thin film layer of vanadium (V) doped zinc oxide (ZnO) is applied on the silicon base.

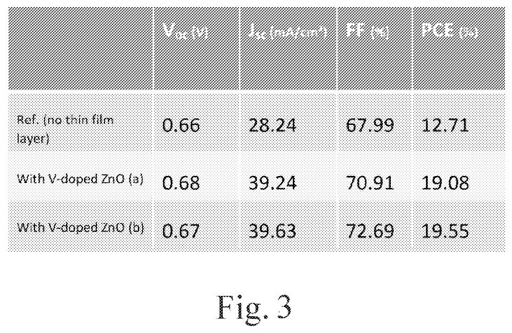

FIG. 3 shows the results of different silicon cells, one sample with no coating or thin film layer and two different samples of silicon coated with vanadium (V) doped zinc oxide (znO).

PCE % refers to power conversion efficiency, FF (fill factor) refers to a measure of the fraction of power utilized in conversion of solar energy, Jsc is the maximum current generated by photo electrons, and Voc is the maximum voltage generated by photo electrons.

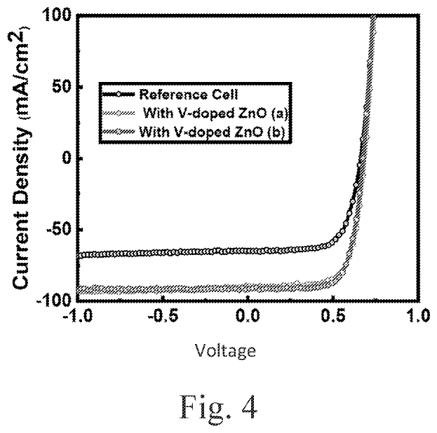

FIG. 4 is a chart with voltage shown on the x-axis and current density on the y-axis. A reference solar cell is compared to two separate V-doped ZnO coated cells.

From the results, it will be appreciated that the power conversion efficiency increases with the addition of the thin film layer.

In another preferred embodiment of the present invention, a photovoltaic solar module is produced by providing a crystalline silicon base. At least one thin film layer of a perovskite precursor solution is applied on the silicon solar cells.

The thin film layer or layers may be installed in a number of ways. In one process, the thin film layer is installed by spin coating an initially liquid layer in a solvent on the silicon base, which dries to result in a thin film solid layer.

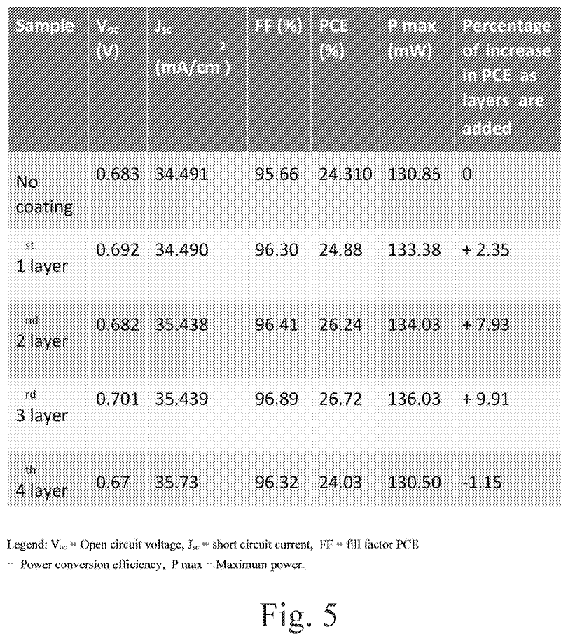

Preliminary studies performed on mixed halide lead perovskites (CH₃NH₃PbI₃) layers applied by spin coating on conventional silicon solar cells show that significant gains in Power Conversion Efficiency (PCE) can be achieved by attaching thin films of suitable thickness, bandgap and thickness on silicon solar cells. Results are summarized in FIG. 5.

The results of different samples are shown-with no coating or film and then with successive layers of thin film coatings.

Power conversion efficiency increased with nano particle layers up to three layers. It will be observed that the power conversion efficiency increases up to ten percent (10%) with three thin film layers.

V_{oc} refers to open circuit voltage; J_{sc} refers to short circuit current; FF refers to fill factor; PCE refers to power conversion efficiency; and P max refers to maximum power.

The present invention may be utilized in the manufacture of solar cell modules and may also be utilized by retrofitting existing silicon modules with the addition of a layer or layers of thin film.

Perovskite emulsions in perovskite precursor solution may also be in the form of cesium lead methyl ammonium perovskites. Experiments show that the precursor solutions spin coated on solar cells less than 16 cm² in area yielded 3% to 5% efficiency increases. However, larger solar cells yielded decreased efficiency boost. Further, long term exposure to air and humidity resulted in degradation of the solution.

In another preferred embodiment of the invention, perovskite nanocrystals or quantum dots (QDs) are applied in an emulsion with a suitable liquid, such as ethanol, and spin coated or sprayed over the surface of a solar cell. Perovskite QDs may be doped with bromine, chlorine, or iodine and may be in the form of CsPbX₃, where X is Br, Cl, or I. Quantum dots may comprise a range of 50 to 1000 atoms and may be a size ranging from 2 to 10 nanometers in diameter.

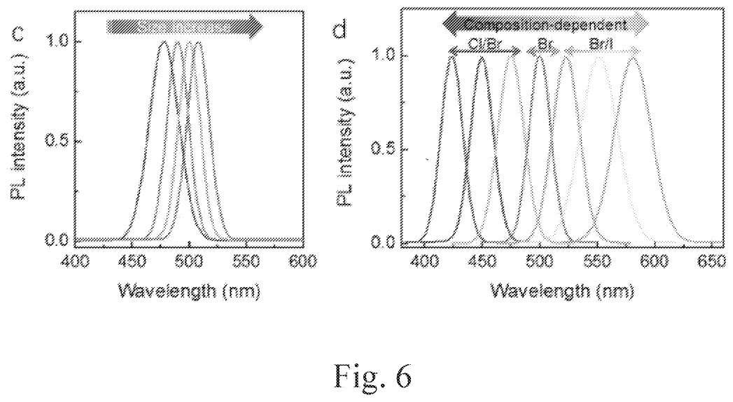

FIG. 6 shows the result of an experiment measuring the photoluminescence of perovskite QDs at various sizes and doping of bromine, chlorine, or iodine. As size increases, higher wavelengths of light are increased. In conjunction, chlorine absorbs light best at lower wavelengths, bromine at medium wavelengths, and iodine at higher wavelengths. Thus, it may be advantageous to provide a solution of perovskite QDs containing various ratios of differently sized and doped QDs.

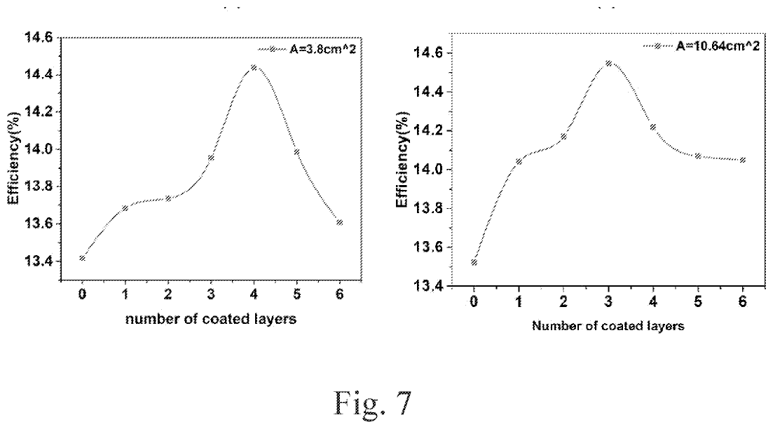

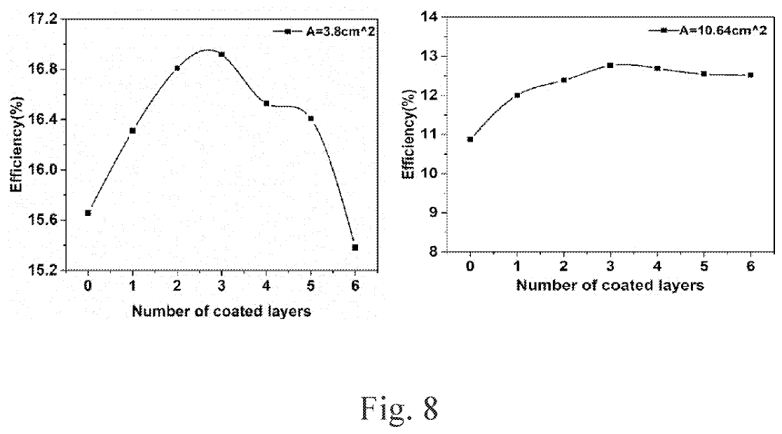

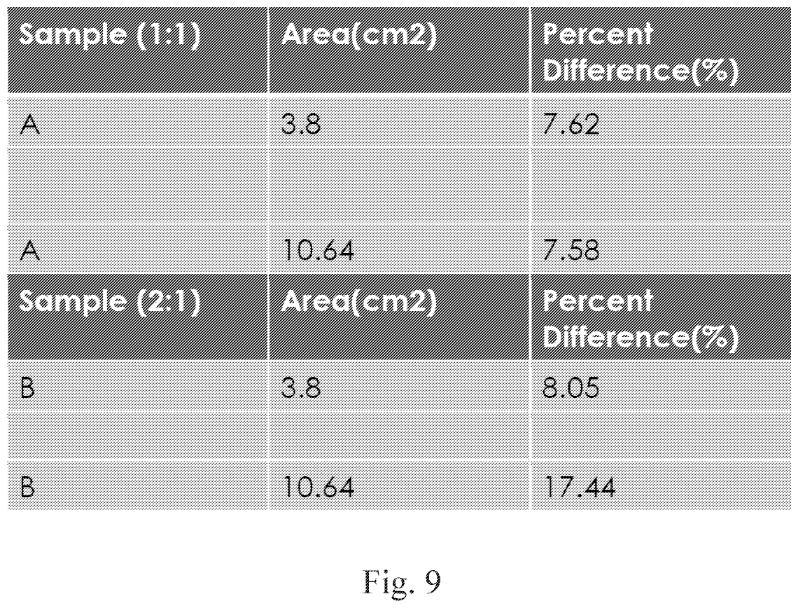

FIG. 7 shows the result of applying perovskite QDs doped at a 1:1 ratio of bromine to chlorine on an area of 3.8 cm² and 10.64cm². FIG. 8 shows the result of applying perovskite QDs doped at a 1:2 ratio of bromine to chlorine on an area of 3.8 cm² and 10.64 cm². As seen in the results table at FIG. 9, mixing the perovskite QDs at different doping ratios can increase the efficiency significantly over standard silicon cells as high as 17.44%.

The present invention may also be embodied in the use of the polymer polydimethylsiloxane, or PDMS, to protect perovskite from environmental degradation. PDMS may be applied in a thin film layer over the top of perovskite precursor solution or perovskite QDs to encapsulate the perovskite layer and further enhance light absorption. PDMS itself may enhance the efficiency of solar cells regardless of the use of perovskite. Preliminary studies show that a layer of PDMS dry spin coated on a silicon cell may enhance efficiency by up to 3%.

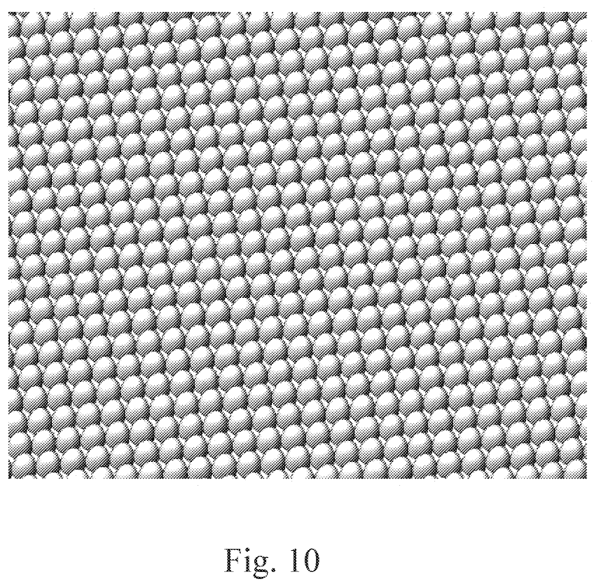

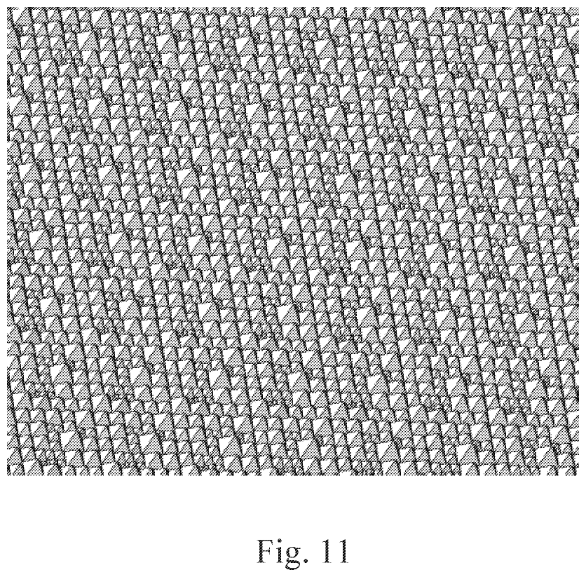

PDMS may be applied in a variety of patterns. These include a moth-eye pattern, as exemplified by the drawing in FIG. 10, and the inverted pyramidal pattern, as exemplified by the drawing in FIG. 11. Preliminary studies show that the inverted pyramidal pattern may provide better solar cell efficiency enhancement.

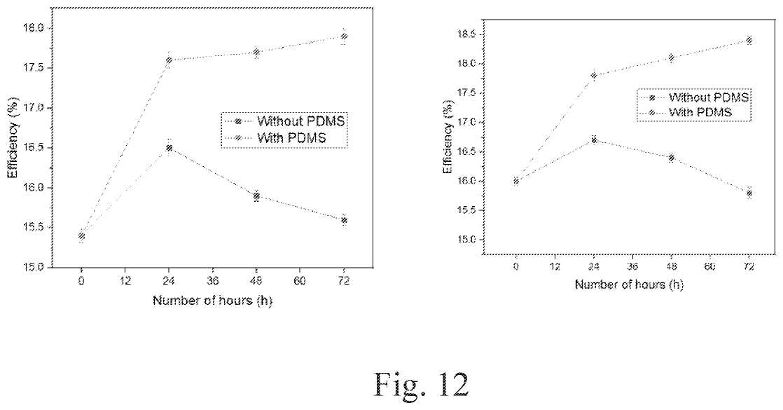

FIG. 12 shows a preliminary study of solar cell efficiency with applied perovskite QDs with PDMS encapsulation and without PDMS encapsulation. Perovskite QDs without PDMS show decreased efficiency over a 72 hour period, showing environmental degradation of the QDs. With PDMS encapsulation, stable efficiency over a 72 hour period is shown with no apparent degradation. Thus a PDMS layer over perovskite QDs may be a critical embodiment of the present invention.

The present invention is further embodied in the method of retrofitting the invention onto existing solar cells. A perovskite quantum dot solution may be spin coated, sprayed, or applied by other appropriate means onto the surface of an existing solar cell in a thin film layer.

The perovskite quantum dot solution may be applied in a plurality of layers. The thickness of the perovskite quantum dot layer may be 100 nm to 900 nm, preferably 150 nm to 400 nm, more preferably 150 nm to 350 nm, and most preferably 150 nm to 250 nm. A layer of PDMS may then be applied by appropriate means over the perovskite quantum dot layer. The thickness of the perovskite quantum dot layer and the PDMS layer together may be 100 microns to 400 microns, preferably 100 microns to 350 microns, more preferably 100 microns to 200 microns, and most preferably 100 microns to 150 microns.

Whereas, the invention has been described in relation to the drawings attached hereto, it should be understood that other and further modifications, apart from those shown or suggested herein, may be made within the scope of this invention.

What is claimed is:

1. A photovoltaic solar cell which comprises:
a planar silicon base; and
at least one thin film layer of vanadium (V) doped zinc oxide (ZnO) on top of said silicon base.

2. The photovoltaic solar cell as set forth in claim 1 wherein said at least one thin film layer of vanadium (V) doped zinc oxide (ZnO) comprises a plurality of thin film layers.

3. The photovoltaic solar cell as set forth in claim 1 wherein said vanadium (V) doped zinc oxide (ZnO) comprises zinc oxide particles doped with vanadium.

4. The photovoltaic solar cell as set forth in claim 1 wherein said at least one thin film layer is fabricated by spincoating.

5. The photovoltaic solar cell as set forth in claim 1 wherein said planar silicon base is crystalline silicon.

6. A method of producing a photovoltaic solar cell, which method comprises:
providing a planar silicon base; and
coating said silicon base with at least one thin film layer of vanadium (V) doped zinc oxide (ZnO) on said silicon base.

7. A method as set forth in claim 6 wherein said at least one thin film layer of vanadium (V) doped zinc oxide (ZnO) comprises a plurality of thin film layers successively applied.

8. A method as set forth in claim 6 wherein said vanadium doped zinc oxide comprises zinc oxide particles doped with vanadium.
a planar silicon base; and
at least one thin film layer of perovskite precursor solution on said silicon base.

10. The photovoltaic solar cell as set forth in claim 9 wherein said at least one thin film layer of perovskite precursor solution comprises a plurality of thin film layers.

11. The photovoltaic solar cell as set forth in claim 9 wherein said at least one thin film layer is fabricated by spincoating.

12. The photovoltaic solar cell as set forth in claim 9 wherein said planar silicon base is crystalline silicon.

13. A method of producing a photovoltaic solar cell, which method comprises:
providing a planar silicon base; and
coating said silicon base with at least one thin film layer of perovskite precursor solution on said silicon base.

14. The method as set forth in claim 13 wherein said at least one thin film layer comprises a plurality of thin film layers successively applied.

15. A photovoltaic solar cell which comprises:
a planar silicon base; and
at least one thin film layer of perovskite quantum dots on said silicon base.

16. The photovoltaic solar cell as set forth in claim 15 wherein said at least one thin film layer of perovskite quantum dots comprises a plurality of thin film layers.

17. The photovoltaic solar cell as set forth in claim 15 wherein said at least one thin film layer is fabricated by spincoating.

18. The photovoltaic solar cell as set forth in claim 15 wherein said planar silicon base is crystalline silicon.

19. A photovoltaic solar cell as set forth in claim 15 further comprising at least one layer of polydimethylsiloxane applied over the at least one thin film layer of perovskite quantum dots.

20. The photovoltaic solar cell as set forth in claim 19 wherein the at least one layer of polydimethylsiloxane is applied in a moth-eye pattern.

21. The photovoltaic solar cell as set forth in claim 19 wherein the at least one layer of polydimethylsiloxane is applied in an inverted pyramidal pattern.

22. The photovoltaic solar cell as set forth in claim 15 wherein said one thin film layer of perovskite quantum dots comprises perovskite quantum dots which are doped with Chlorine, Bromine, or Iodine.

23. The photovoltaic solar cell as set forth in claim 22 wherein said one thin film layer of perovskite quantum dots comprise a ratio of 1:2 perovskite quantum dots doped with Bromine to perovskite quantum dots doped with Chlorine.

25. The method of producing a photovoltaic solar cell, which method comprises:
providing a planar silicon base;
doping perovskite quantum dots with Chlorine, Bromine, or Iodine; and
coating said silicon base with at least one thin film layer of said perovskite quantum dots.

25. The method as set forth in claim 25 wherein said at least one thin film layer of perovskite quantum dots comprises a plurality of thin film layers successively applied.

26. The method as set forth in claim 25 further comprising the step of applying a layer of polydimethylsiloxane over the at least one thin film layer of perovskite quantum dots.
